(19) United States
(12) Patent Application Publication
(10) Pub. No.: US 2024/0260286 A1
(43) Pub. Date: Aug. 1, 2024

(54) DISPLAY PANEL AND DISPLAY DEVICE INCLUDING THE SAME

(71) Applicant: LG Display Co., Ltd., Seoul (KR)

(72) Inventors: Sungjin KIM, Seoul (KR); Taewoon KO, Seoul (KR); Jinhyung JUNG, Goyang-si (KR); Suhyun PARK, Busan (KR)

(73) Assignee: LG Display Co., Ltd., Seoul (KR)

(21) Appl. No.: 18/400,810

(22) Filed: Dec. 29, 2023

(30) Foreign Application Priority Data
Jan. 31, 2023 (KR) 10-2023-0013293

(51) Int. Cl. H10K 39/34; G06V 40/12; G06V 40/16; G09G 3/3208; H10K 59/124

(52) U.S. Cl. CPC H10K 39/34; G06V 40/12; G06V 40/16; G09G 3/3208; H10K 59/124; G09G 2300/0452; G09G 2300/0861; G09G 2354/00

(57) ABSTRACT

The invention relates to a display panel and display device including the same. A display panel including a substrate including a first area and a second area; at least one light-emitting element disposed in the first area and configured to emitting light; and at least one light-sensing element disposed in the second area and configured to sense an infrared signal. Further, the at least one light-sensing element includes a first pattern including a strain inducing material patterned into a non-flat shape on the substrate; and a thin-film semiconductor disposed on the first pattern.

### CROSS-REFERENCE TO RELATED APPLICATIONS

This application claims priority from Korean Patent Application No. 10-2023-0013293 filed on Jan. 31, 2023, in the Republic of Korea, the entire contents of which are hereby expressly incorporated by reference into the present application.

### BACKGROUND OF THE DISCLOSURE

### Field of Invention

The present disclosure relates to a display panel when a light-sensing element is disposed, and a display device including the same.

### Background Art

A flat panel display device includes an organic light-emitting display device having advantages such as improved luminous efficiency, fast response speed, and wide viewing angle compared to a liquid crystal display device. However, the organic light-emitting display device still has low luminous efficiency, contains an organic material and is vulnerable to moisture (e.g., from the outside), and thus, reliability and lifespan thereof can deteriorate.

Recently, a micro light-emitting diode display device as an inorganic light-emitting display device has been proposed. The micro light-emitting diode display device includes inorganic light-emitting diodes with a size of 100 micrometers or smaller disposed in each pixel to display an image. In the micro light-emitting diode display device, a process of transferring the micro light-emitting diodes grown on a single crystal substrate to an array substrate of the display device using a stamp is performed.

### SUMMARY OF THE DISCLOSURE

In one example, biometric recognition using a SWIR (Short-Wave Infrared Ray) signal has less noise compared to an image using light of a visible-light ray or near infrared ray (NIR) wavelength, and the SWIR is less absorbed by blood or tissue and thus can penetrate deeper into the skin. In addition, a light-sensing device with a SWIR detectable material can view a higher-quality image due to less scattering characteristics, and has the possibility of vein recognition with excellent security and precision compared to face recognition and fingerprint recognition. When applying SWIR, light power can be freely controlled, and visual stability can be improved.

However, to manufacture an infrared sensor in a photoelectric effect scheme, a minimum energy (bandgap) required for a light absorbing semiconductor material to absorb light, must be lower than an infrared light energy. In more detail, a related art light absorbing semiconductor material has a flat shape and can detect a near-infrared signal with a wavelength of 800 nanometers (nm), but has difficulties detecting the near-infrared signal with a wavelength greater than 1,100 nanometers (nm), due to band gap limitations. Further, a compound semiconductor has a high material cost, a high manufacturing cost, and a low operating temperature.

Accordingly, to address the above-mentioned problem, the present disclosure provides a display device capable of detecting a near-infrared signal having a wavelength of 1,100 nanometers or greater. In more detail, the present disclosure provides a display panel including a light-sensing element exceeding the bandgap limit disposed in the vicinity of a light-emitting element embodied as a micro light-emitting diode, and is capable of detecting an infrared signal having a wavelength of 1,100 nanometers or greater.

Further, the present disclosure provides a display panel including a light-sensing element disposed around the light-emitting element and being composed of a combination of a stress induction pattern and a thin-film semiconductor. Further, the micro light-emitting diode and the light-sensing element are disposed in the same layer or in different layers. Thus, the light-sensing element can detect a long-wavelength infrared signal, thereby achieving improved face recognition and fingerprint recognition.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims or combinations thereof.

A display panel according to an embodiment of the present disclosure includes a substrate including a first area and a second area; at least one light-emitting element disposed in the first area; and at least one light-sensing element disposed in the second area. In addition, the light-sensing element can include a first pattern that induces a stress, wherein the first pattern has a convex or concave shape.

A display device according to an embodiment of the present disclosure includes a substrate including a first area and a second area; at least one light-emitting element disposed in the first area; and at least one light-sensing element disposed in the second area, wherein the light-sensing element is disposed on the substrate, wherein a first insulating layer is disposed on the light-sensing element, wherein the light-emitting element is disposed on the first insulating layer, wherein a second insulating layer is disposed on the light-emitting element.

A display device according to another embodiment of the present disclosure includes a substrate including a first area and a second area; at least one light-emitting element disposed in the first area; and at least one light-sensing element disposed in the second area, wherein a first insulating layer is disposed on the substrate, wherein the light-emitting element and the light-sensing element are disposed on the first insulating layer, wherein a second insulating layer is disposed on the light-emitting element and the light-sensing element.

A display device according to still another embodiment of the present disclosure includes a substrate including a first area and a second area; at least one light-emitting element disposed in the first area; and at least one light-sensing element disposed in the second area, wherein a buffer layer is disposed on the substrate, wherein a thin-film transistor and the light-sensing element are disposed on the buffer layer, wherein a passivation layer is disposed on the thin-film transistor and the light-sensing element, wherein a planarization layer is disposed on the passivation layer, wherein the light-emitting element is disposed on the planarization layer, wherein an encapsulation layer is disposed on the light-emitting element.

A display device according to still yet another embodiment of the present disclosure includes a substrate including a first area and a second area; at least one light-emitting element disposed in the first area; and at least one light-sensing element disposed in the second area, wherein a first insulating layer is disposed on the substrate, wherein the light-emitting element is disposed on the first insulating layer, wherein a second insulating layer is disposed on the light-emitting element, wherein a buffer layer is disposed on the second insulating layer, wherein the light-sensing element is disposed on the buffer layer, wherein a passivation layer is disposed on the light-sensing element.

Details of other embodiments are included in the detailed description and drawings.

According to the embodiments of the present disclosure, the light-sensing elements can be disposed around the light-emitting elements and can detect an infrared signal having a wavelength of 1,100 nanometers (nm) or greater.

Further, the light-sensing elements can be disposed around the light-emitting elements, thereby providing a display device with low noise and high face recognition and fingerprint recognition ability.

Also, the display device capable of performing vein recognition with superior security and precision compared to face recognition and fingerprint recognition can be provided.

In addition, due to the display panel in which the light-sensing elements are disposed, the display device can overcome the extinction coefficient limitation of a planar semiconductor. The stress induction pattern can be applied to the light-sensing element in a simple and inexpensive manner, such that the light absorption wavelength range of the display device extends to the short-wave infrared ray.

The light-sensing elements can be disposed in the non-light-emitting area, such that deterioration in resolution can be minimized. Further, the stress inducing pattern can be formed in various forms of a block, or a concave shape, hemispherical shape, a cone, or a pyramid shape (for example, a triangular pyramid), and these shape aid in reducing the band gap.

Effects of the present disclosure are not limited to the effects as mentioned above, and other effects not mentioned will be clearly understood by those skilled in the art from the descriptions below.

In addition to the effects as described above, specific effects of the present disclosure will be described together while describing specific details for carrying out the present disclosure.

### BRIEF DESCRIPTION OF DRAWINGS

The present invention will become more fully understood from the detailed description given hereinbelow and the accompanying drawings, which are given by illustration only, and thus are not limitative of the present invention, and wherein:

FIG. 1 is a plan view showing a display device according to an embodiment of the present disclosure.

FIG. 2 is a cross-sectional view taken along a cutting line 2-2 in FIG. 1.

FIG. 3 is a diagram showing an example of arrangement of a light-emitting element and a light-sensing element according to an embodiment of the present disclosure.

FIG. 4 is a diagram showing an example of a structure of a light-sensing element according to an embodiment of the present disclosure.

FIGS. 5 and 6 are diagrams showing an example of a ratio of a height and a width of a first pattern of a light-sensing element according to an embodiment of the present disclosure.

FIG. 7 is a diagram showing an example of a manufacturing process of a light-sensing element according to an embodiment of the present disclosure.

FIG. 8 is a diagram illustrating an example of a biometric recognition operation of a light-sensing element according to an embodiment of the present disclosure.

FIG. 9 is a diagram showing an example when a light-sensing element according to an embodiment of the present disclosure is disposed on a display panel.

FIG. 10 shows a cross-sectional view taken along a cutting line 10 in FIG. 9.

FIG. 11 is a diagram showing a stack structure of a light-emitting element and a light-sensing element disposed according to a first embodiment of the present disclosure.

FIG. 12 is a diagram showing a stack structure of a light-emitting element and a light-sensing element disposed according to a second embodiment of the present disclosure.

FIG. 13 is a diagram showing an arrangement of a light-emitting element and a light-sensing element adjacent thereto according to a third embodiment of the present disclosure.

FIG. 14 is a cross-sectional view of a light-emitting element and a light-sensing element according to the third embodiment of the present disclosure as cut along a cutting line 15 of FIG. 14.

FIG. 15 is a cross-sectional view showing a stack structure of a light-emitting element and a light-sensing element according to a fourth embodiment of the present disclosure.

FIGS. 16 and 17 are diagrams showing a manufacturing process of a display device according to an embodiment of the present disclosure.

### DETAILED DESCRIPTION OF THE EMBODIMENTS

Advantages and features of the present disclosure, and a method of achieving the advantages and features will become apparent with reference to embodiments described later in detail together with the accompanying drawings. However, the present disclosure is not limited to the embodiments as disclosed under, but can be implemented in various different forms. Thus, these embodiments are set forth only to make the present disclosure complete, and to completely inform the scope of the present disclosure to those of ordinary skill in the technical field to which the present disclosure belongs, and the present disclosure is only defined by the scope of the claims.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth to provide a thorough understanding of the present disclosure. However, it will be understood that the present disclosure can be practiced without these specific details. Examples of various embodiments are illustrated and described further below. It will be understood that the description herein is not intended to limit the claims to the specific embodiments described. On the contrary, it is intended to cover alternatives, modifications, and equivalents as can be included within the spirit and scope of the present disclosure as defined by the appended claims.

A shape, a size, a ratio, an angle, a number, etc. disclosed in the drawings for describing embodiments of the present disclosure are illustrative, and the present disclosure is not limited thereto. The same reference numerals refer to the same elements herein. Further, descriptions and details of well-known steps and elements are omitted for simplicity of the description. Furthermore, in the following detailed description of the present disclosure, numerous specific details are set forth to provide a thorough understanding of the present disclosure. However, it will be understood that the present disclosure can be practiced without these specific details. In other instances, well-known methods, procedures, components, and circuits have not been described in detail so as not to unnecessarily obscure aspects of the present disclosure.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “including”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements can modify the entire list of elements and may not modify the individual elements of the list. In interpretation of numerical values, an error or tolerance therein can occur even when there is no explicit description thereof.

In addition, it will also be understood that when a first element or layer is referred to as being present “on” a second element or layer, the first element can be disposed directly on the second element or can be disposed indirectly on the second element with a third element or layer being disposed between the first and second elements or layers. It will be understood that when an element or layer is referred to as being “connected to”, or “coupled to” another element or layer, it can be directly on, connected to, or coupled to the other element or layer, or one or more intervening elements or layers can be present. In addition, it will also be understood that when an element or layer is referred to as being “between” two elements or layers, it can be the only element or layer between the two elements or layers, or one or more intervening elements or layers can also be present.

Further, as used herein, when a layer, film, region, plate, or the like is disposed “on” or “on a top” of another layer, film, region, plate, or the like, the former can directly contact the latter or still another layer, film, region, plate, or the like can be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like is disposed “below” or “under” another layer, film, region, plate, or the like, the former can directly contact the latter or still another layer, film, region, plate, or the like can be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

In descriptions of temporal relationships, for example, temporal precedent relationships between two events such as “after”, “subsequent to”, “before”, etc., another event can occur therebetween unless “directly after”, “directly subsequent” or “directly before” is not indicated.

When a certain embodiment can be implemented differently, a function or an operation specified in a specific block can occur in a different order from an order specified in a flowchart. For example, two blocks in succession can be actually performed substantially concurrently, or the two blocks can be performed in a reverse order depending on a function or operation involved.

It will be understood that, although the terms “first”, “second”, “third”, and so on can be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described under could be termed a second element, component, region, layer or section, without departing from the spirit and scope of the present disclosure.

The features of the various embodiments of the present disclosure can be partially or entirely combined with each other, and can be technically associated with each other or operate with each other. The embodiments can be implemented independently of each other and can be implemented together in an association relationship. In interpreting a numerical value, the value is interpreted as including an error range unless there is no separate explicit description thereof.

It will be understood that when an element or layer is referred to as being “connected to”, or “coupled to” another element or layer, it can be directly on, connected to, or coupled to the other element or layer, or one or more intervening elements or layers can be present. In addition, it will also be understood that when an element or layer is referred to as being “between” two elements or layers, it can be the only element or layer between the two elements or layers, or one or more intervening elements or layers can also be present.

The features of the various embodiments of the present disclosure can be partially or entirely combined with each other, and can be technically associated with each other or operate with each other. The embodiments can be implemented independently of each other and can be implemented together in an association relationship.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning for example consistent with their meaning in the context of the relevant art and will not be interpreted in an idealized or overly formal sense unless expressly so defined herein.

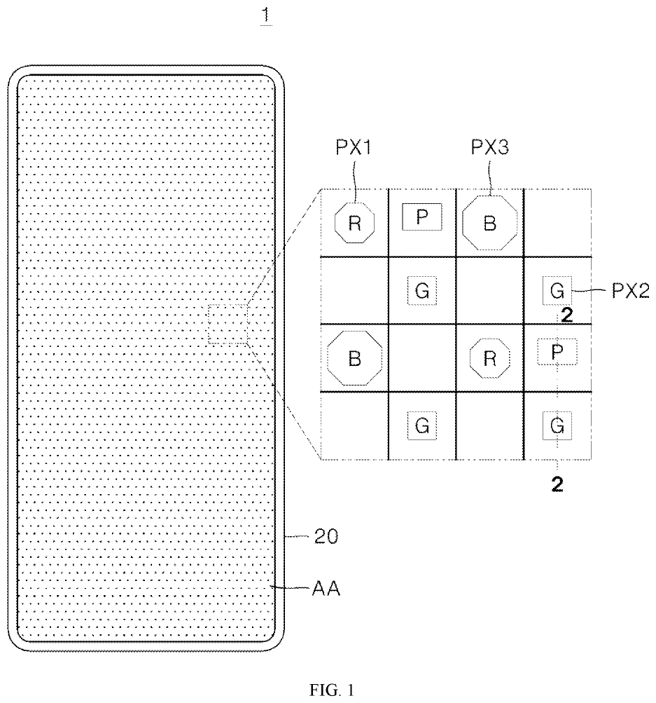

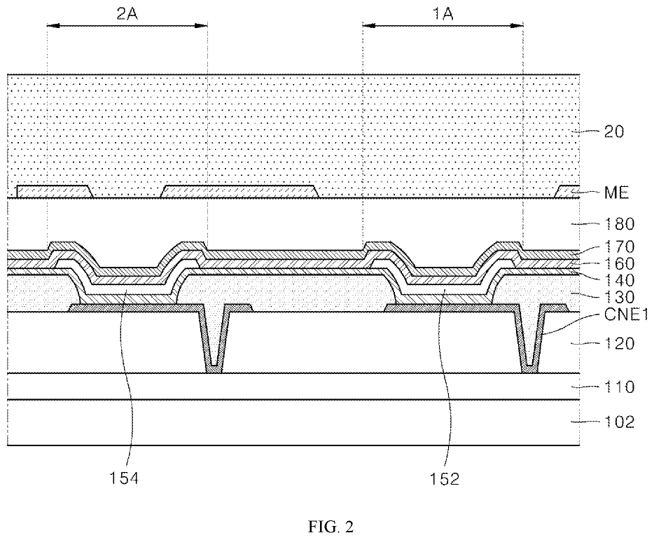

Hereinafter, display devices according to embodiments of the present disclosure will be described in detail with reference to the accompanying drawings. In particular, FIG. 1 is a plan view showing a display device 1 according to an embodiment of the present disclosure, and FIG. 2 is a cross-sectional view taken along the cutting line 2-2 in FIG. 1.

Referring to FIGS. 1 and 2, the display device 1 according to an embodiment of the present disclosure can include a cover member 20 constituting a front surface of the display device, a plurality of light-emitting elements PX1 to PX3, and a plurality of light-sensing elements P. Further, the display device 1 includes a display area or an active area AA. The display area AA can include a first area 1A and a second area 2A. The display device 1 can include a substrate 102 including the first area 1A and the second area 2A. The first area 1A can include a light-emitting area, and the second area 2A can include a non-light-emitting area. At least one light-emitting element PX1 to PX3 is disposed in the first area 1A, while at least one light-sensing element P is disposed in the second area 2A.

Also, the light-sensing element can be marked with ‘P’ or ‘PD’. At least one light-emitting element PX1 to PX3 can include the first sub-pixel PX1 emitting red (R) light, the second sub-pixel PX2 emitting green (G) light, and the third sub-pixel PX3 emitting blue (B) light. Each of at least one light-emitting element PX1 to PX3 can include a micro light-emitting diode chip or an organic light-emitting diode.

In the display area AA, the second area 2A can be disposed adjacent to the first area 1A, and the light-sensing elements P can be disposed in the second area 2A. The display device 1 can include the display area AA and a bezel area on the front surface thereof. The bezel area can be disposed along the outermost edge of the display device 1 so as to surround the display area AA.

In addition, the cover member 20 can be referred to as a cover glass and include a cover window and a cover glass. The cover member 20 constitutes the front surface of the display device and protects the display device from external impact. An edge portion of the cover member 20 can have a round shape curved toward a rear surface of the display device.

The cover member 20 also includes the display area AA that displays a screen, and can be made of a transparent material, such as a cover glass, to display a screen. For example, the cover member 20 can be made of a transparent plastic material, a glass material, or a tempered glass material.

A front surface of the cover member 20 can be divided into the display area AA and a non-display area or a non-active area NA other than the display area AA. The non-display area NA is formed along an edge of the display area AA, constitutes a front surface of the cover member 20 and is defined as the bezel area. A rear surface of the cover member 20 can include the non-display area NA. Also, the non-display area NA is disposed between the rear surface of the cover member 20 and an upper surface of the back frame.

A display module coupled to the rear surface of the cover member 20 can include a bent area located in the bezel area at the rear surface of the cover member 3 facing in a −Z axis direction. To reduce the bezel area at the rear surface of cover member 20, the curvature radius of the bent area can be reduced. The radius of curvature of the bent area is proportional to a total thickness of the display device 1. When the total thickness increases, the radius of curvature of the bent area increases. Conversely, when the total thickness decreases, the radius of curvature of the bent area decreases. Therefore, in order not to increase the size of the bezel area, the overall thickness of the display device 1 is considered.

Further, the substrate 102 can be made of plastic having flexibility. For example, the substrate 102 can be composed of a single layer or a stack of multiple layers made of polyimide, polyethylene terephthalate, polyethylene naphthalate, polycarbonate, polyethersulfone, polyarylate, polysulfone, or cyclic-olefin copolymer, or any combination thereof. However, the present disclosure is not limited thereto. The substrate 102 can be made of glass.

Referring to FIG. 2, a pixel driving layer 110 can be disposed on the substrate 102. The pixel driving layer 110 can include a plurality of thin-film transistors using an amorphous silicon semiconductor, a polycrystalline silicon semiconductor, or an oxide semiconductor, and at least one storage capacitor. Accordingly, the pixel driving layer 110 can be referred to as a thin-film transistor (TFT) layer 110. The plurality of thin-film transistors can include at least one driving thin-film transistor, and at least one switching thin-film transistor. When the pixel driving layer 110 includes the plurality of thin-film transistors, the pixel driving layer 110 can be formed on the substrate 102 in a TFT manufacturing process.

The pixel driving layer 110 can include a pixel driver chip manufactured on a single crystal semiconductor substrate using a metal-oxide-semiconductor field-effect transistor (MOSFET) manufacturing process. The pixel driver chip can include a plurality of circuit units, and each circuit unit can include at least one driving transistor, at least one switching transistor, and at least one storage capacitor. An adhesive layer can be disposed on the substrate 102 and then the pixel driver chip can be mounted on an adhesive layer in a transfer process. The adhesive layer can be made of acryl resin, silicone resin, etc. However, the present disclosure is not limited thereto.

As shown in FIG. 2, a first planarization layer 120 can be disposed on the TFT layer 110. The first planarization layer 120 can be made of an organic insulating material, for example, photosensitive photo acryl or photosensitive polyimide. However, the present disclosure is not limited thereto. At least one connection electrode CNE1 and a bank layer 130 can be disposed on the first planarization layer 120.

The connection electrode CNE1 can have a single-layer or multi-layer structure, and can made of one or more of aluminum (Al), titanium (Ti), copper (Cu), molybdenum (Mo), tantalum (Ta), titanium nitride (TiN), or tantalum nitride (TaN). An insulating layer can also be disposed between the first planarization layer 120 and the bank layer 130. The insulating layer can be made of an organic insulating material such as photosensitive photo acryl or photosensitive polyimide. However, the present disclosure is not limited thereto. The insulating layer can be composed of a single layer or a stack of multiple layers made of an inorganic insulating material, such as silicon oxide, silicon nitride, silicon oxynitride, or aluminum oxide, or a combination thereof. However, the present disclosure is not limited thereto.

As shown, a plurality of banks can be disposed in the bank layer 130. When one pixel includes three sub-pixels, for example, a red sub-pixel, a green sub-pixel, and a blue sub-pixel, three banks can be disposed in one pixel. The number of the banks in one pixel can be equal to the number of sub-pixels included in one pixel. The bank can be made of an organic insulating material, such as photosensitive photo acryl or photosensitive polyimide, or a combination thereof. However, the present disclosure is not limited thereto.

A first electrode 140 can be disposed on the connection electrode CNE1. The first electrode 140 can be, for example, an anode electrode. A light-emissive layer 152 can be disposed on the first electrode 140 and in the first area 1A. A light-sensing layer 154 can be disposed on the first electrode 140 and in the second area 2A. An insulating layer 160 can be disposed on the light-emissive layer 152, the light-sensing layer 154, and the first electrode 140. The insulating layer 160 can be made of an organic insulating material such as photosensitive photo acryl or photosensitive polyimide. However, the present disclosure is not limited thereto. The insulating layer can be composed of a single layer or a stack of multiple layers of an inorganic insulating material, such as silicon oxide, silicon nitride, silicon oxynitride, or aluminum oxide. However, the present disclosure is not limited thereto.

A second electrode 170 can be disposed on the insulating layer 160 and can be, for example, a cathode electrode. An encapsulation layer 180 can be disposed on the second electrode 170. At least one metal mesh electrode ME can be disposed on the encapsulation layer 180 and can be spaced from each other by a regular spacing. A cover member 20 can be disposed on at least one metal mesh electrode ME and the encapsulation layer 180.

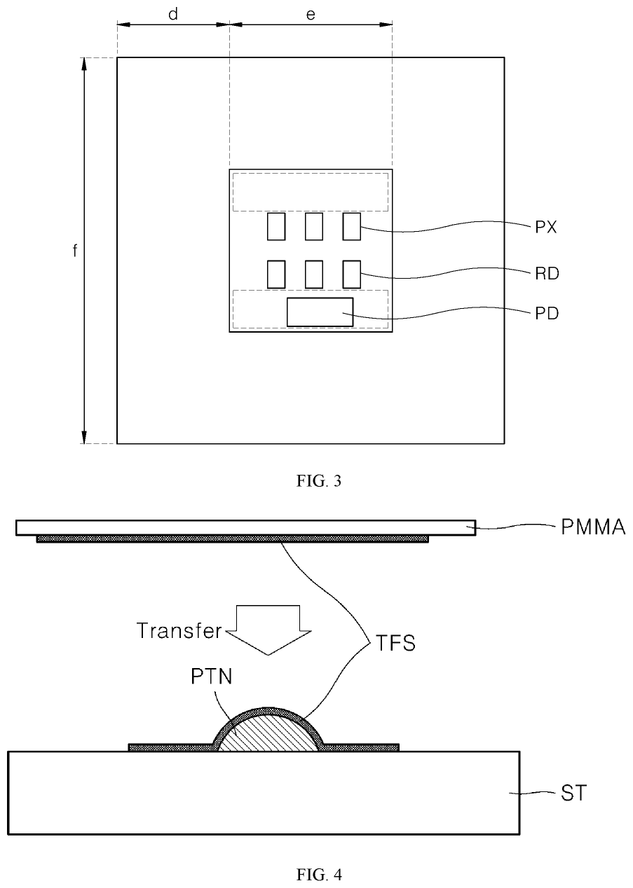

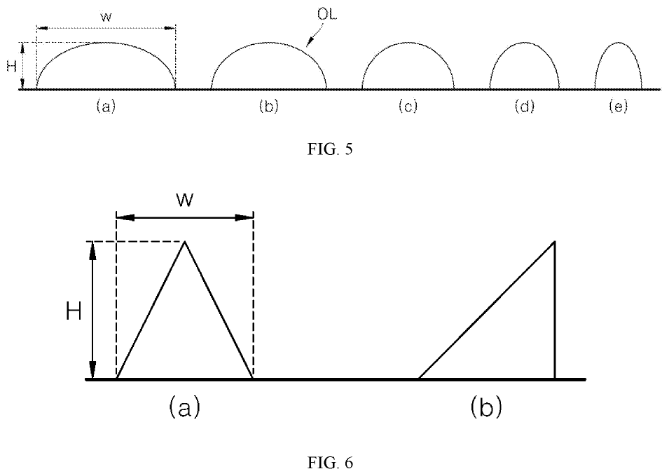

Next, FIG. 3 is a diagram showing an example of arrangement of a light-emitting element and a light-sensing element according to an embodiment of the present disclosure. Also, FIG. 4 is a diagram showing a structure example of a light-sensing element according to an embodiment of the present disclosure, and FIGS. 5 and 6 are diagrams showing an example of a ratio of a height and a width of a first pattern of a light-sensing element according to an embodiment of the present disclosure.

Referring to FIG. 3, at least one light-emitting element PX is disposed in the first area 1A, and the light-sensing element PD can be disposed in the second area 2A. Further, in the first area 1A, at least one redundant light-emitting element RD can be disposed to correspond to at least one light-emitting element PX.

The light-emitting element PX, for example, one pixel can include light-emitting elements PX1 to PX3 emitting light of three colors, respectively. The first light-emitting element PX1 can be a red (R) light-emitting element, the second light-emitting element PX2 can be a green (G) light-emitting element, and the third light-emitting element PX3 can be a blue (B) light-emitting element. Two light-emitting elements can be mounted on each bank layer 130. One of the two light-emitting elements disposed on the bank layer 130 can be a main light-emitting element, and the other of the two light-emitting elements disposed thereon may be a redundant light-emitting element RD.

Each of the light-emitting elements PX1 to PX3 can be embodied as an inorganic light-emitting diode. The inorganic light-emitting diode can have a size of 1 to 100 μm, 1 to 50 μm, or 1 to 20 μm in a horizontal direction (in an X-axis direction or in a Y-axis direction). The inorganic light-emitting diode can be referred to as a micro light-emitting diode. Further, the inorganic light-emitting diode can include a p-doped semiconductor layer, an n-doped semiconductor layer, and an active layer disposed therebetween. The active layer can include, for example, one or more quantum well layers. Moreover, the inorganic light-emitting diode can include a first electrode connected to the p-doped semiconductor layer and a second electrode connected to the n-doped semiconductor layer. The inorganic light-emitting diode can be manufactured using a group II-VI or III-V compound semiconductor. The inorganic light-emitting diode can be manufactured in a separate manufacturing process, and can be disposed onto the adhesive layer in the transfer process.

A spacing d from the outermost edge of the substrate 102 to the first area 1A can be 200 micrometers or smaller. This spacing d can be a grinding margin. A width e of the first area 1A when at least one light-emitting element PX and at least one redundant light-emitting element RD are disposed can be, for example, 434 micrometers ((m). Further, a width e of the second area 2A where at least one light-sensing element PD is disposed can be 434 micrometers (μm) equal to the width of the first area 1A. A length f of one pixel area including the first area 1A and the second area 2A can be, for example, 834 micrometers (μm) or smaller.

Referring to FIG. 4, each light-sensing element PD can include a first pattern (strain-inducing pattern) PTN for inducing a stress; and a thin-film semiconductor TFS disposed on the first pattern. The first pattern PTN can include an inorganic film or an organic film and have a convex shape or a concave shape. In more detail, the first pattern PTN can have a shape of one of a hemisphere, a cone, and a pyramid (for example, a triangular pyramid). Further, the light-sensing element PD includes the thin-film semiconductor TFS formed on a PMMA (polymethylmethacrylate) film and transferred onto the first pattern PTN convex on a sample stage ST.

Referring to FIG. 5, a ratio of a height H and a width W of the first pattern PTN of the light-sensing element PD can be 1:1, 1:1.5, 1:2, 1:2.5, or 1:3. In more detail, the ratio of the height H and the width W of the first pattern PTN of the light-sensing element PD can be 1:3 as shown in FIG. 5(a), 1:2.5 as shown in FIG. 5(b), 1:2 as shown FIG. 5(c), 1:1.5 as shown in FIG. 5(d), and 1:1 as shown in FIG. 5(e). The first pattern PTN can include a material that induces a stress of 1% to 3% and can include a pattern that induces the stress in a uniaxial or biaxial manner.

Further, the thin-film semiconductor TFS can detect an infrared signal. In particular, the thin-film semiconductor TFS can include a material that detects the infrared signal having a wavelength of 1,100 nanometers (nm) or greater. The thin-film semiconductor TFS can have a thickness of 5 to 50 nanometers (nm) and can include silicon. Referring to FIG. 6, the first pattern PTN of the light-sensing element PD can have a shape of an isosceles triangle or a right triangle. In this instance, the ratio of the height and the width can be 1:1.

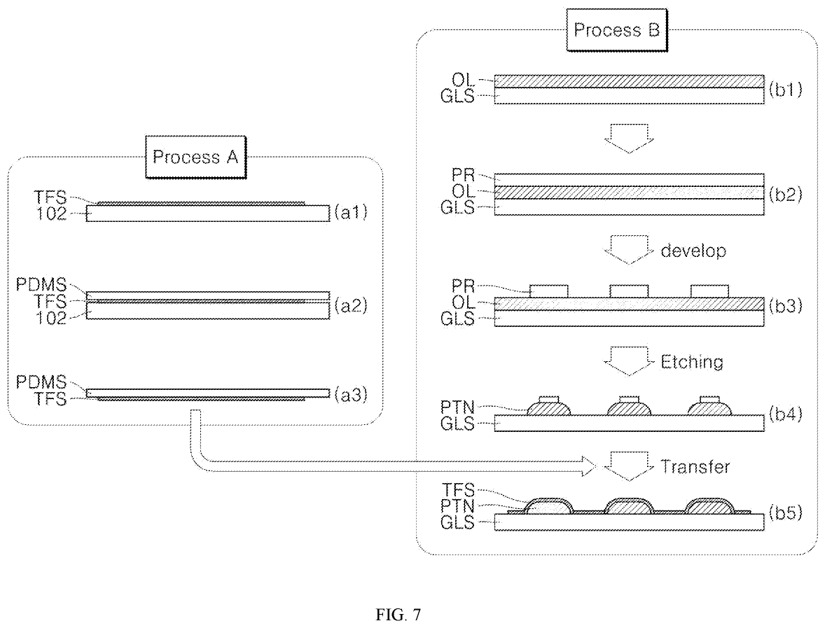

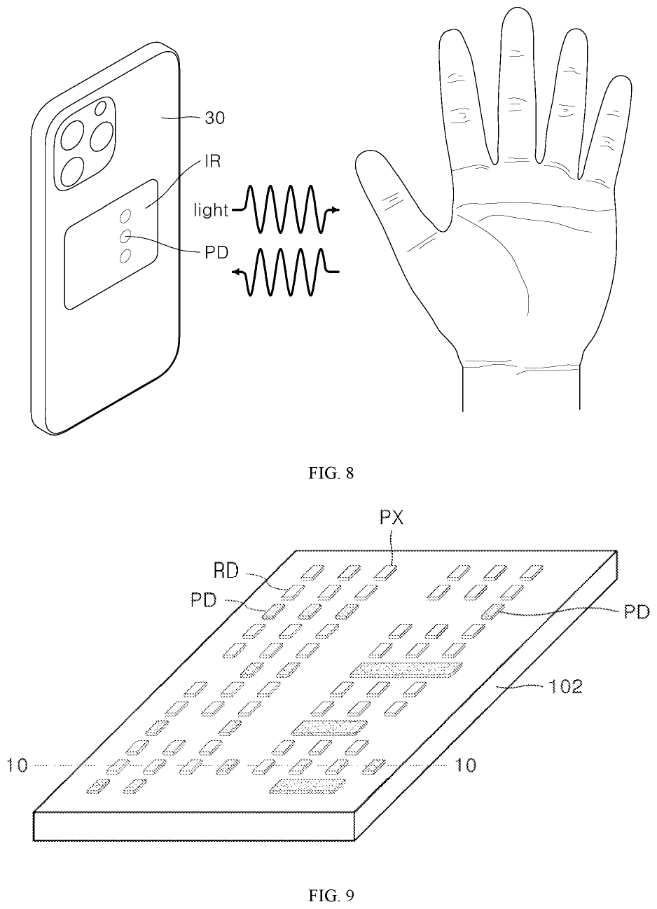

Next, FIG. 7 is a diagram showing an example of a manufacturing process of a light-sensing element according to an embodiment of the present disclosure. In addition, FIG. 8 is a diagram illustrating an example of a biometric recognition operation of a light-sensing element according to an embodiment of the present disclosure.

Referring to FIG. 7, the manufacturing process of the light-sensing element PD includes a process A of transferring the thin-film semiconductor TFS and a process B in which the thin-film semiconductor TFS is stress-induced by the first pattern PTN. First, in the process A, the thin-film semiconductor TFS is disposed on substrate 102 in step (a1). In addition, the thin-film semiconductor TFS can include, for example, molybdenum disulfide (MoS2). Then, a silicone oil layer (Polydimethylsiloxane; PDMS) or a polymethylmethacrylate (PMMA) film can be disposed on the thin-film semiconductor TFS in step (a2). The substrate 102 can then be removed in step (a3).

In one example, in the process B, an organic film OL or an inorganic film can be disposed on a substrate GLS made of a glass, in step (b1). Then, a photoresistor PR can be disposed on the inorganic film or the organic film OL in step (b2). Subsequently, the photoresistor PR can be developed into several photoresistor patterns PR with a predefined width in step (b3). Then, a portion of the inorganic film or the organic film OL overlapping each of the developed photoresistor patterns PR can be etched so as to have a convex shape in step (b4). Subsequently, the thin-film semiconductor TFS formed in the process A can be transferred onto the convex portion of the inorganic film or the organic film OL in step (b5).

Therefore, the convex-shaped portion of the inorganic film or the organic film OL can constitute the first pattern PTN, and the thin-film semiconductor TFS can be disposed on the first pattern PTN. Thus, the light-sensing element PD can be formed through the processes as described above. Also, the thin-film semiconductor TFS made of the light-responsive material formed on the first pattern PTN as the stress-inducing pattern can have a bandgap smaller than a basic bandgap so as to absorb a short-wave infrared ray.

Referring to FIG. 8, the light-sensing element PD formed by the above process can be disposed on a back frame 30 located on a rear surface of the display device 1. That is, the display device 1 can include the back frame 30 disposed at the rear surface thereof to accommodate a display module and contact the cover member 20 to support the cover member 20. Thus, the back frame 30 can serve as a housing constituting the rear surface of the display device 1, and can be made of a polymer epoxy-based resin material.

In this instance, the back frame can function as a casing constituting the outermost portion of the display device 1. However, the present disclosure is not limited thereto. For example, the back frame can function as a middle frame serving as a housing protecting a rear surface of the display module. At least one light-sensing element PD can be disposed on the back frame 30. An infrared ray emitter IR can be further disposed on the back frame 30. Accordingly, infrared light emitted from the infrared ray emitter IR can reach the user's hand, be reflected therefrom, and then be received by the light-sensing element PD.

The display device 1 can include an infrared light-sensing unit including an emitter and a receiver in an area facing the user's palm on the back frame 30 of the rear surface thereof. The emitter can be implemented as the infrared ray emitter IR, and the receiver can be implemented as the light-sensing element PD. Accordingly, the infrared ray emitter IR can transmit the infrared signal, and the light-sensing element PD can receive and detect the infrared signal. The light-sensing element PD can detect a short-wave infrared wavelength band. Therefore, palm vein recognition through the infrared light-sensing unit can improve security and convenience compared to conventional face and iris recognitions.

Further, when the user holds the mobile display device 1 with their hand, the infrared light-sensing unit can recognize the veins of the user's palm. Thus, it is simple to operate the display device 1. User resistance to use of the display device 1 is reduced.

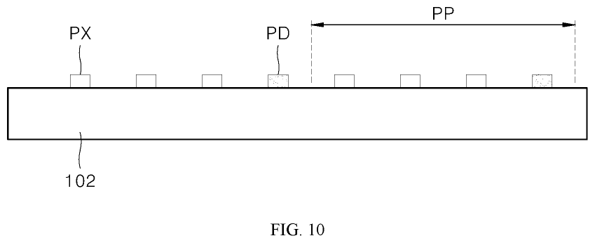

Next, FIG. 9 is a view showing an example of the light-sensing elements disposed on a display panel according to an embodiment of the present disclosure, and FIG. 10 is a view showing a cross-sectional view taken along a cutting line 10 of FIG. 9. Referring to FIG. 9, each of the light-sensing elements PD is disposed in a corresponding manner to each of the redundant light-emitting elements RD corresponding to each of the light-emitting elements PX respectively emitting light of red (R), green (G), and blue (B). Alternatively, the light-sensing element PD can be disposed in a corresponding manner to one of the redundant light-emitting elements RD corresponding to each of the light-emitting elements PX respectively emitting light of red (R), green (G), and blue (B).

Further, each of the light-sensing elements PD according to an embodiment of the present disclosure can have a width equal to a width of each of the redundant light-emitting elements RD corresponding to each of the light-emitting elements PX respectively emitting light of red (R), green (G), and blue (B).

Referring to FIG. 10, a pixel pitch PP of one pixel area can correspond to a spacing between light-sensing elements PD adjacent to each other. In the spacing, at least three light-emitting elements PX respectively emitting light of red (R), green (G), and blue (B) can be disposed.

As described above, the light-sensing element PD according to an embodiment of the present disclosure is located in an area other than the sub-pixel in the pixel area, and thus easily detects light over a large-area, and thus can provide higher resolution in applications such as biometrics such as remote healthcare and biometric authentication, etc.

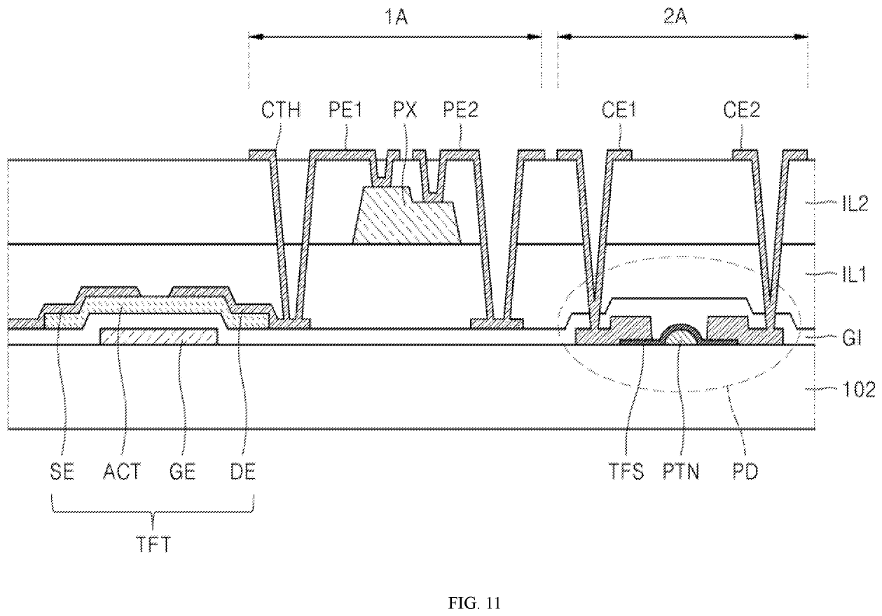

Next, FIG. 11 is a diagram showing a stack structure of a light-emitting element and a light-sensing element disposed according to a first embodiment of the present disclosure. The display device 1 according to the first embodiment of the present disclosure includes the substrate 102 including the first area 1A and the second area 2A; at least one light-emitting element PX1 to PX3 disposed in the first area; and at least one light-sensing element PD disposed in the second area.

Referring to FIG. 11, the light-sensing element PD is disposed on the substrate 102, a first insulating layer IL1 is disposed on the light-sensing element PD, the light-emitting element PX is disposed on the first insulating layer IL1, and a second insulating layer IL2 is disposed on the light-emitting element PX. The light-sensing element PD is disposed on the substrate 102 and in the second area 2A. One side electrode PE1 of the light-emitting element PX extends in a through hole of the first insulating layer IL1 and the second insulating layer IL2 to connect to one electrode DE of the thin-film transistor TFT.

The light-emitting element PX and the light-sensing element PD according to the first embodiment of the present disclosure can be stacked as follows in more detail. The light-sensing element PD can be disposed in the second area 2A and on substrate 102. Also, a gate electrode GE of the thin-film transistor TFT can be disposed in an area other than the first and second areas and on the substrate 102.

The light-sensing element PD can have the first pattern PTN disposed on the substrate 102, and the thin-film semiconductor TFS disposed on the first pattern PTN. Lower ends of a first connection electrode CE1 and a second connection electrode CE2 can be disposed at both opposing ends of the thin-film semiconductor TFS, respectively.

A gate insulating film GI can be disposed on the light-sensing element PD and the gate electrode GE. As shown, the thin-film transistor TFT incudes the gate electrode GE, a portion of the gate insulating film GI disposed on the gate electrode GE, a semiconductor layer ACT disposed on the gate insulating film GI, and a source electrode SE and a drain electrode DE respectively disposed on both opposing sides of the semiconductor layer ACT. The first insulating layer IL1 can be disposed on the source electrode SE and drain electrode DE of the thin-film transistor TFT, and the gate insulating film GI.

The light-emitting element PX can be disposed on the first insulating layer IL1 and in the first area 1A. The second insulating layer IL2 can be disposed on the first insulating layer IL1 and the light-emitting element PX. One side electrode PE1 and the other side electrode PE2 of the light-emitting element PX, and the first connection electrode CE1, and the second connection electrode CE2 of the light-sensing element PD can be disposed on the second insulating layer IL2.

In the first area 1A, one side electrode PE1 of the light-emitting element PX can fill a contact-hole CTH extending through hole of the first insulating layer IL1 and the second insulating layer IL2 and can be connected to one electrode DE of the thin-film transistor TFT. In the second area 2A, the first connection electrode CE1 can extend in a through hole of the first insulating layer IL1 and the second insulating layer IL2 to connect to one side of the thin-film semiconductor TFS. The second connection electrode CE2 can extend in the through hole of the first insulating layer IL1 and the second insulating layer IL2 to connect to the other side of the thin-film semiconductor TFS.

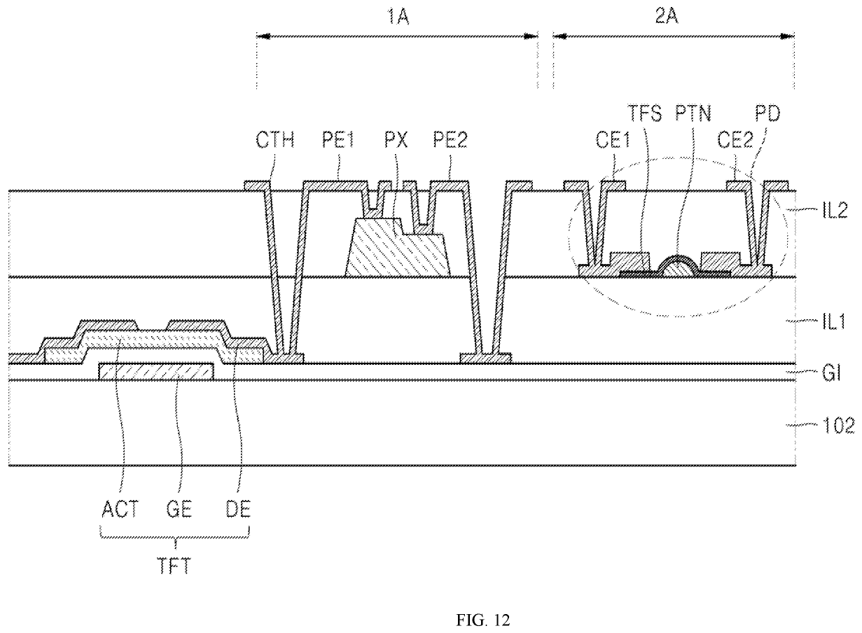

Next, FIG. 12 is a diagram showing a stack structure of a light-emitting element and a light-sensing element disposed according to a second embodiment of the present disclosure. The display device 1 according to the second embodiment of the present disclosure can include the substrate 102 including the first area 1A and the second area 2A; at least one light-emitting element PX1 to PX3 disposed in the first area; and at least one light-sensing element PD disposed in the second area.

Referring to FIG. 12, the first insulating layer IL1 can be disposed on the substrate 102, the light-emitting element PX and the light-sensing element PD can be disposed on the first insulating layer IL1, and the second insulating layer IL2 can be disposed on the light-emitting element PX and the light-sensing element PD. The light-sensing element PD can be disposed on the substrate 102 and in the second area 2A. One side electrode PE1 of the light-emitting element PX can extend through hole of the first insulating layer PL1 and the second insulating layer PL2 so as to be connected to one electrode DE of the thin-film transistor TFT.

The light-emitting element PX and the light-sensing element PD according to the second embodiment of the present disclosure can be stacked as follows in more detail. The light-sensing element PD can be disposed in the second area 2A and on substrate 102. A gate electrode GE of the thin-film transistor TFT can be disposed in an area other than the first and second areas and on the substrate 102.

The thin-film transistor TFT can have the gate electrode GE, a portion of the gate insulating film GI disposed on the gate electrode GE, a semiconductor layer ACT disposed on the gate insulating film GI, and a source electrode SE and a drain electrode DE respectively disposed on both opposing sides of the semiconductor layer ACT. In the first area 1A and the second area 2A, the gate insulating film GI can be disposed on the substrate 102. In an area other than the first and second areas, the gate electrode GE can be disposed on the substrate 102, and the gate insulating film GI can be disposed on the gate electrode GE.

The first insulating layer IL1 can be disposed on the gate insulating film GI. The light-emitting element PX can be disposed in the first area 1A and on the first insulating layer IL1. The light-sensing element PD can be disposed in the second area 2A and on the first insulating layer IL1.

The light-sensing element PD can include the first pattern PTN disposed on the first insulating layer IL1, and the thin-film semiconductor TFS disposed on the first pattern PTN. Lower ends of the first connection electrode CE1 and the second connection electrode CE2 of the light-sensing element PD can be disposed at both opposing ends of the thin-film semiconductor TFS, respectively.

The second insulating layer IL2 can be disposed on the light-emitting element PX in the first area 1A, the light-sensing element PD in the second area 2A, and the first insulating layer IL1. One side electrode PE1 and the other side electrode PE2 of the light-emitting element PX, and the first connection electrode CE1 and the second connection electrode CE2 of the light-sensing element PD can be disposed on the second insulating layer IL2.

In the first area 1A, one side electrode PE1 of the light-emitting element PX can fill a contact-hole CTH extending through hole of the first insulating layer IL1 and the second insulating layer IL2 and can be connected to one electrode DE of the thin-film transistor TFT. In the second area 2A, the first connection electrode CE1 can extend through hole of the second insulating layer IL2 so as to be connected to one side of the thin-film semiconductor TFS. The second connection electrode CE2 can extend through hole of the second insulating layer IL2 so as to be connected to the other side of the thin-film semiconductor TFS.

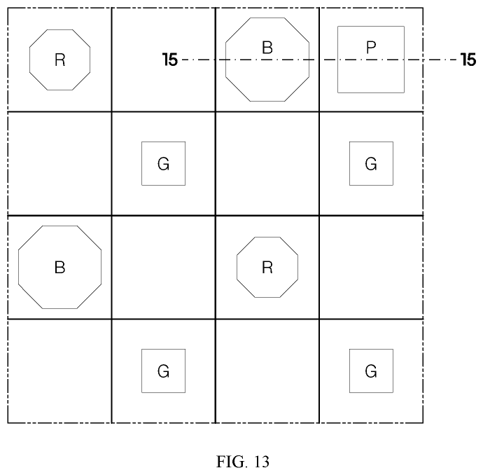

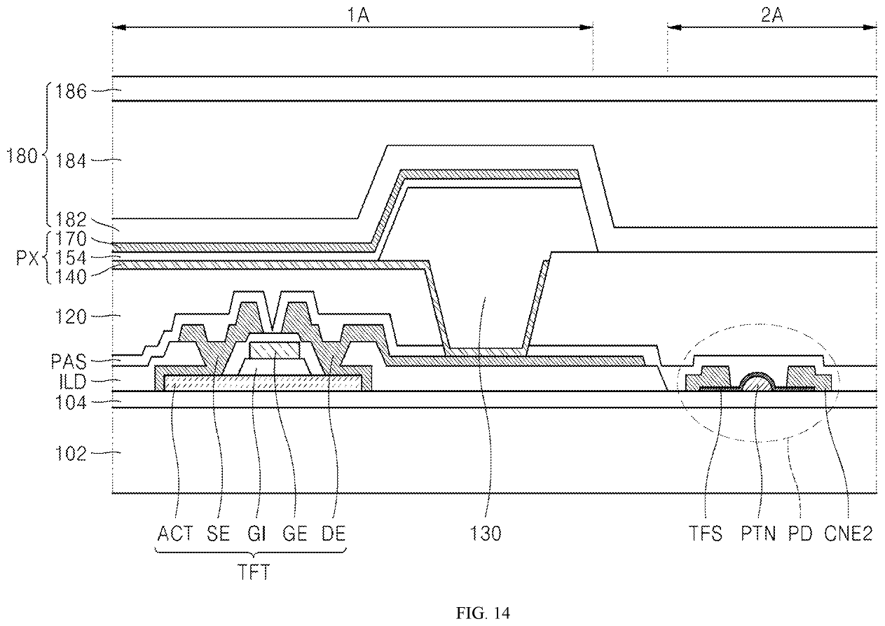

Next, FIG. 13 is a diagram showing arrangement of a light-emitting element and a neighboring light-sensing element according to a third embodiment of the present disclosure. Also, FIG. 14 is a cross-sectional view showing a light-emitting element and a light-sensing element according to the third embodiment of the present disclosure as cut along a cutting line 15-15 of FIG. 13.

The display device 1 according to the third embodiment of the present disclosure can include the substrate 102 including the first area 1A and the second area 2A; at least one light-emitting element PX1 to PX3 disposed in the first area (with PX1 to PX3 being spaced apart from one another); and at least one light-sensing element PD disposed in the second area. Referring to FIG. 13 and FIG. 14, a buffer layer 104 can be disposed on the substrate 102. The thin-film transistor TFT and the light-sensing element PD can be disposed on the buffer layer 104.

A passivation layer PAS can be disposed on the thin-film transistor TFT and the light-sensing element PD. A planarization layer 120 can be disposed on the passivation layer PAS. The light-emitting element PX can be disposed on the planarization layer 120. An encapsulation layer 180 can be disposed on the light-emitting element PX and can encapsulate the light-emitting element PX.

A first electrode 140 of the light-emitting element PX can extend through hole of the planarization layer 120 and the passivation layer PAS so as to be connected to one electrode DE of the thin-film transistor TFT. One electrode DE of the thin-film transistor TFT can be, for example, a drain electrode.

The light-emitting element PX and the light-sensing element PD according to the third embodiment of the present disclosure can be stacked as follows in more detail. The thin-film transistor TFT can be disposed on the substrate 102 and in the first area 1A. The light-sensing element PD can be disposed on the substrate 102 and in the second area 2A. For example, the buffer layer 104 can be disposed on the substrate 102, the thin-film transistor TFT can be disposed in the first area 1A and on the buffer layer 104, while the light-sensing element PD can be disposed in the second area 2A and on the buffer layer 104.

The thin-film transistor TFT can include the active layer ACT disposed on the buffer layer 104, the gate insulating film GI disposed on the active layer ACT, the gate electrode GE disposed on the gate insulating film GI, a portion of an interlayer insulating film ILD disposed on the gate electrode GE, and a source electrode SE and a drain electrode DE disposed on the interlayer insulating film ILD. The passivation layer PAS can be disposed on the source electrode SE and the drain electrode DE. The source electrode SE can extend through hole of the interlayer insulating film ILD so as to be connected to one side of the active layer ACT, while the drain electrode DE can extend through hole of the interlayer insulating film ILD so as to be connected to the other side of the active layer ACT.

The light-sensing element PD can include the first pattern PTN disposed on the buffer layer 104, the thin-film semiconductor TFS disposed on the first pattern PTN, and connection electrodes CNE2 disposed at both opposing ends of the thin-film semiconductor TFS, respectively. The planarization layer 120 can be disposed on the passivation layer PAS. The light-emitting element PX can be disposed in the first area 1A and on the planarization layer 120. The encapsulation layer 180 can be disposed on the light-emitting element PX.

The light-emitting element PX can include the first electrode 140 disposed on the planarization layer 120, the bank 130 disposed on the first electrode 140, the light-emissive layer 154 disposed on the first electrode 140 and the bank 130, and the second electrode 170 disposed on the light-emissive layer 154. The first electrode 140 can act as an anode electrode, and the second electrode 170 can act as a cathode electrode.

The encapsulation layer 180 can prevent penetration of external moisture or oxygen into the light-emitting element PX for example vulnerable to external moisture or oxygen. To this end, the encapsulation layer 180 can include at least one inorganic encapsulation layer and at least one organic encapsulation layer. However, the present disclosure is not limited thereto. In the present disclosure, a structure of the encapsulation layer 180 when a first encapsulation layer 182, a second encapsulation layer 184, and a third encapsulation layer 186 are sequentially stacked will be described by way of example.

The first encapsulation layer 182 can be formed over the substrate 102 so as to cover the second electrode 170 as the cathode electrode. The second encapsulation layer 184 can be disposed on the first encapsulation layer 182. The third encapsulation layer 186 can cover the second encapsulation layer 184. The first encapsulation layer 182 and the third encapsulation layer 186 can minimize or prevent penetration of external moisture or oxygen into the light-emitting element PX. Each of the first encapsulation layer 182 and the third encapsulation layer 186 can be made of an inorganic insulating material which can be deposited at a low-temperature, such as silicon nitride (SiNx), silicon oxide (SiOx), silicon oxynitride (SiON), or aluminum oxide (Al2O3). Since each of the first encapsulation layer 182 and the third encapsulation layer 186 can be deposited in a low-temperature atmosphere, damage to the light-emitting element PX which is vulnerable to a high-temperature atmosphere can be prevented during a deposition process of the first encapsulation layer 182 and the third encapsulation layer 186.

The second encapsulation layer 184 can serve as an impact absorbing layer to relieve a stress between the layers due to the bending of the display device 1, and can planarize a step occurring between the layers. The second encapsulation layer 184 can be made of a non-photosensitive organic insulating material such as acryl resin, epoxy resin, phenolic resin, polyamide resin, polyimide resin and polyethylene or silicon oxycarbon (SiOC), or a photosensitive organic insulating material such as photo acryl. However, the present disclosure is not limited thereto.

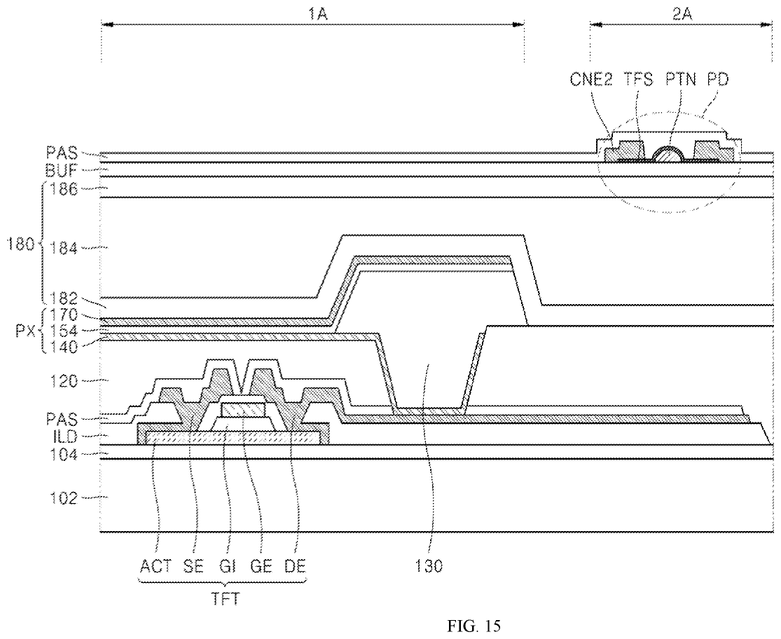

FIG. 15 is a cross-sectional view showing a stack structure of a light-emitting element and a light-sensing element according to a fourth embodiment of the present disclosure. The display device 1 according to the fourth embodiment of the present disclosure can include the substrate 102 including the first area 1A and the second area 2A; at least one light-emitting element PX1 to PX3 disposed in the first area; and at least one light-sensing element PD disposed in the second area.

Referring to FIG. 15, a buffer layer 104 can be disposed on the substrate 102. The thin-film transistor TFT can be disposed on the first buffer layer 104. A first insulating layer 120 can be disposed to cover the thin-film transistor TFT disposed on the first buffer layer 104. The light-emitting element PX can be disposed on the first insulating layer 120. A second insulating layer 180 can be disposed on the light-emitting element PX. A second buffer layer BUF can be disposed on the second insulating layer 180. The light-sensing element PD can be disposed on the second buffer layer BUF. The passivation layer PAS can be disposed on the light-sensing element PD. The first insulating layer 120 can act as a planarization layer, and the second insulating layer 180 can act as an encapsulation layer.

Further, the thin-film transistor TFT can be disposed on the substrate 102 and in the first area 1A. One side electrode 140 of the light-emitting element PX can extend through the first insulating layer 120 so as to be connected to one electrode DE of the thin-film transistor TFT. One side electrode 140 of the light-emitting element PX can act as an anode electrode. The light-emitting element PX and the light-sensing element PD according to the fourth embodiment of the present disclosure can be stacked as follows in more detail.

The thin-film transistor TFT can be disposed on the substrate 102 and in the first area 1A. For example, the first buffer layer 104 can be disposed on the substrate 102. The thin-film transistor TFT can be disposed in the first area 1A and on the first buffer layer 104.

The thin-film transistor TFT can include the active layer ACT disposed on the first buffer layer 104, the gate insulating film GI disposed on the active layer ACT, the gate electrode GE disposed on the gate insulating film GI, a portion of the interlayer insulating film ILD disposed on the gate electrode GE, and a source electrode SE and a drain electrode DE disposed on the interlayer insulating film ILD. The passivation layer PAS can be disposed on the source electrode SE and the drain electrode DE. The source electrode SE can extend through hole of the interlayer insulating film ILD so as to be connected to one side of the active layer ACT, while the drain electrode DE can extend through hole of the interlayer insulating film ILD so as to be connected to the other side of the active layer ACT.

The planarization layer 120 can be disposed on the passivation layer PAS. The light-emitting element PX can be disposed in the first area 1A and on the planarization layer 120. The encapsulation layer 180 can be disposed on the light-emitting element PX.

The light-emitting element PX can include the first electrode 140 disposed on the planarization layer 120, the bank 130 disposed on the first electrode 140, the light-emissive layer 152 disposed on the first electrode 140 and the bank 130, and the second electrode 170 disposed on the light-emissive layer 152. The first electrode 140 can act as an anode electrode, and the second electrode 170 can act as a cathode electrode.

The encapsulation layer 180 can be disposed on the light-emitting element PX and in the first area 1A and the second area 2A. The encapsulation layer 180 can include the first encapsulation layer 182, the second encapsulation layer 184, and the third encapsulation layer 186. In the first area 1A and the second area 2A, the second buffer layer BUF can be disposed on the encapsulation layer 180. The light-sensing element PD can be disposed in the second area 2A and on the second buffer layer BUF.

The light-sensing element PD can include the first pattern PTN disposed on the second buffer layer BUF, the thin-film semiconductor TFS disposed on the first pattern PTN, and the connection electrodes CNE2 disposed at both opposing ends of the thin-film semiconductor TFS, respectively.

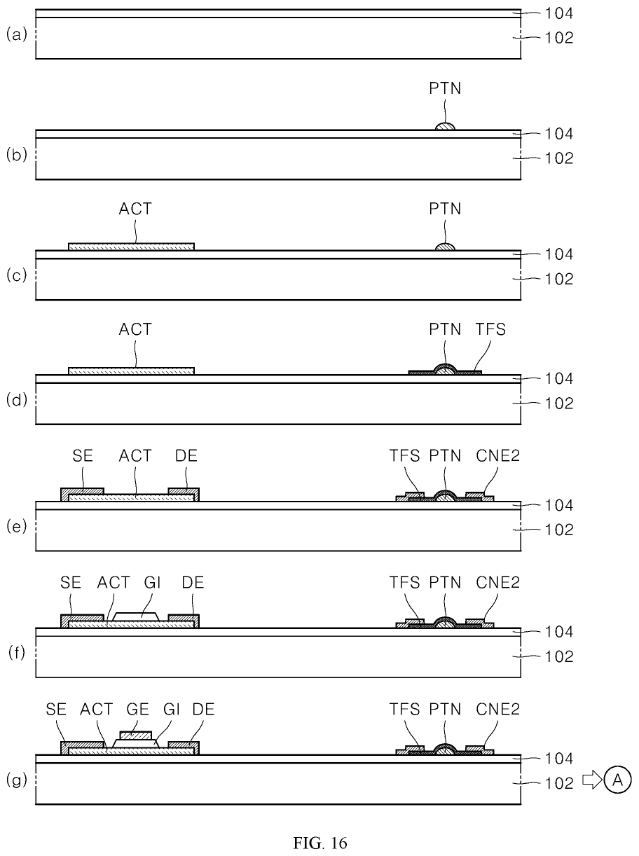

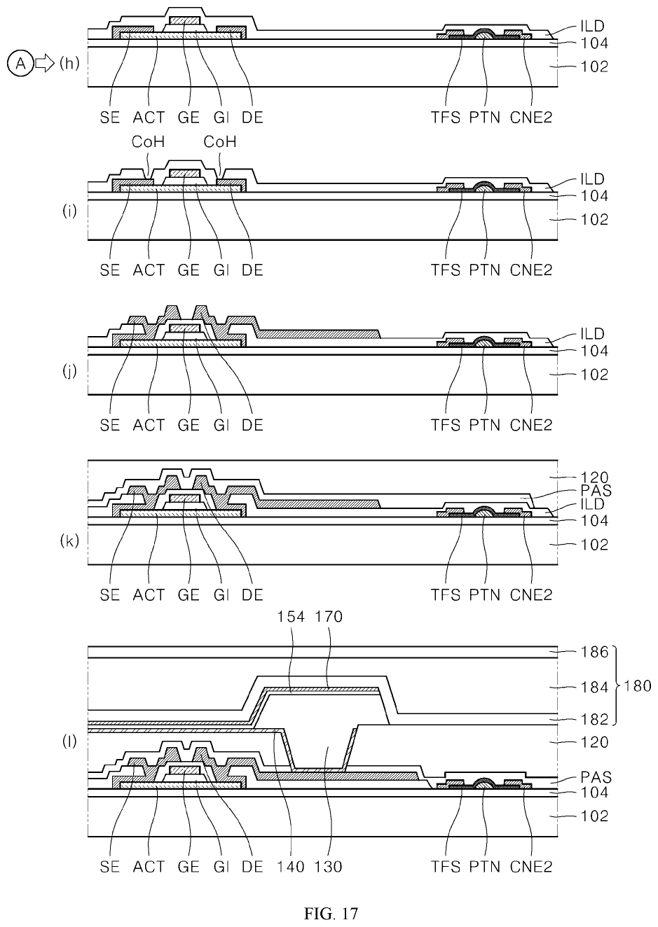

Next, FIGS. 16 and 17 are diagrams showing a manufacturing process of a display device according to an embodiment of the present disclosure. Referring to FIGS. 16 and 17, in the manufacturing process of the display device 1 according to the present disclosure, the buffer layer 104 can be first disposed on the substrate 102 in step (a), and the first pattern PTN can be disposed on the buffer layer 104 in step (b). The active layer ACT can be disposed on the buffer layer 104 in step (c) at a location spaced from the first pattern PTN.

Next, the thin-film semiconductor TFS can be disposed on the first pattern PTN in step (d), and the connection electrode CNE2 can be disposed on the thin-film semiconductor TFS while the source electrode SE and the drain electrode DE can be disposed on the active layer ACT in step (e). Subsequently, the gate insulating film GI can be disposed on the active layer ACT in step (f), and the gate electrode GE can be disposed on the gate insulating film GI in step (g).

Subsequently, the interlayer insulating film ILD can be disposed on the buffer layer 104, the source electrode SE, the active layer ACT, the gate electrode GE, the drain electrode DE, the connection electrode CNE2, and the thin-film semiconductor TFS in step (h) shown in FIG. 17. Subsequently, a contact-hole CoH can be defined in a portion of the interlayer insulating film ILD on each of the source electrode SE and the drain electrode DE in step (i). A source connection electrode SE and a drain connection electrode DE can be disposed on the interlayer insulating film ILD in step (j).

The planarization layer 120 can be disposed on the interlayer insulating film ILD, the source connection electrode SE and the drain connection electrode DE in step (k). Further in step (k), the first electrode 140 of the light-emitting element PX can be disposed on the planarization layer 120. Then a bank 130 can be disposed on the first electrode 140 in step (1). The light-emissive layer 154 can be disposed on the first electrode 140 and the bank 130, and the second electrode 170 can be disposed on the light-emissive layer 154, and the encapsulation layer 180 can be disposed on the second electrode 170 in step (1). The first electrode 140 can be an anode electrode, and the second electrode 170 can be a cathode electrode. That is, steps (a)-(l) of FIGS. 16 and 17 can be performed in the order shown and as described above.

The encapsulation layer 180 can have a structure when the second encapsulation layer 184 is disposed on the first encapsulation layer 182, and the third encapsulation layer 186 is disposed on the second encapsulation layer 184. Each of the first encapsulation layer 182 and the third encapsulation layer 186 can include an inorganic material such as silicon nitride (SiNx), and the second encapsulation layer 184 can include an organic material.

In the above process, the light-sensing element PD can be disposed adjacent to the light-emitting element PX. When the stress is applied to the thin-film semiconductor TFS of the light-sensing element PD, a basic band gap of the thin-film semiconductor TFS can be reduced.

Accordingly, when the stress is applied to the light-sensing element PD according to an embodiment of the present disclosure, the light-sensing element PD can generate a bandgap smaller than the basic bandgap due to the thin-film semiconductor TFS, thereby absorbing the short-wave infrared ray.

As described above, according to an embodiment of the present disclosure, the light-sensing elements exceeding the bandgap limit can be disposed in the vicinity of the light-emitting elements embodied as the micro light-emitting diodes. Thus, the display panel capable of detecting the infrared signal having a wavelength of 1,100 nanometers (nm) or greater and the display device including the same can be realized.

A display panel according to the embodiments of the present disclosure can be described as follows. A first aspect of the present disclosure provides a display panel comprising: a substrate including a first area 1A and a second area 2A; at least one light-emitting element PX1 to PX3 disposed in the first area 1A; and at least one light-sensing element PD disposed in the second area 2A.

In some implementations of the first aspect, the first area 1A is a light-emitting area, and the second area 2A is a non-light-emitting area. In some implementations of the first aspect, the display panel further comprises at least one redundant light-emitting element RD disposed in the first area 1A in a corresponding manner to the at least one light-emitting element.

In some implementations of the first aspect, each of the at least one light-sensing element PD includes a first pattern PTN and a thin-film semiconductor TFS disposed on the first pattern. In some implementations of the first aspect, the first pattern includes an inorganic film or an organic film. In some implementations of the first aspect, the first pattern has a convex shape or a concave shape. In some implementations of the first aspect, the first pattern has a shape of one of a hemisphere, a cone, and a triangular pyramid. In some implementations of the first aspect, the first pattern has a ratio of a height and a width in a range of 0.3 to 1 or 1 to 3. In some implementations of the first aspect, the first pattern has a ratio of a height and a width which is one of 1:1, 1:1.5, 1:2, 1:2.5, or 1:3.

In some implementations of the first aspect, the first pattern includes a material inducing a stress of 1% to 3%. In some implementations of the first aspect, the first pattern includes a pattern inducing a stress in in a uniaxial or biaxial manner. In some implementations of the first aspect, the display panel further comprises an infrared ray emitter emitting an infrared signal, wherein the thin-film semiconductor detects the infrared signal. In some implementations of the first aspect, the infrared signal has a wavelength of 1,100 nanometers (nm) or greater. In some implementations of the first aspect, the thin-film semiconductor has a thickness of 1 to 50 nanometers (nm). In some implementations of the first aspect, the thin-film semiconductor includes silicon.

In some implementations of the first aspect, each of the at least one light-emitting element PX1 to PX3 includes a micro light-emitting diode chip. In some implementations of the first aspect, each of the at least one light-emitting element PX1 to PX3 includes an organic light-emitting diode.

A second aspect of the present disclosure provides a display device comprising: a substrate including a first area 1A and a second area 2A; at least one light-emitting element PX1 to PX3 disposed in the first area 1A; and at least one light-sensing element PD disposed in the second area 2A, wherein the light-sensing element is disposed on the substrate, wherein a first insulating layer is disposed on the light-sensing element, wherein the light-emitting element is disposed on the first insulating layer, wherein a second insulating layer is disposed on the light-emitting element.

In some implementations of the second aspect, a thin-film transistor is disposed on the substrate and in the first area 1A, wherein one side electrode of the light-emitting element extends through hole of the first insulating layer and the second insulating layer so as to be connected to one electrode of the thin-film transistor.

A third aspect of the present disclosure provides a display device comprising: a substrate including a first area 1A and a second area 2A; at least one light-emitting element PX1 to PX3 disposed in the first area 1A; and at least one light-sensing element PD disposed in the second area 2A, wherein a first insulating layer is disposed on the substrate, wherein the light-emitting element and the light-sensing element are disposed on the first insulating layer, wherein a second insulating layer is disposed on the light-emitting element and the light-sensing element.

In some implementations of the third aspect, a thin-film transistor is disposed on the substrate and in the first area 1A, wherein one side electrode of the light-emitting element extends through hole of the first insulating layer and the second insulating layer and is connected to one electrode of the thin-film transistor.

A fourth aspect of the present disclosure provides a display device comprising: a substrate including a first area 1A and a second area 2A; at least one light-emitting element PX1 to PX3 disposed in the first area 1A; and at least one light-sensing element PD disposed in the second area 2A, wherein a buffer layer is disposed on the substrate, wherein a thin-film transistor and the light-sensing element are disposed on the buffer layer, wherein a passivation layer is disposed on the thin-film transistor and the light-sensing element, wherein a planarization layer is disposed on the passivation layer, wherein the light-emitting element is disposed on the planarization layer, wherein an encapsulation layer is disposed on the light-emitting element.

In some implementations of the fourth aspect, one side electrode of the light-emitting element extends through hole of the planarization layer and the passivation layer so as to be connected to one electrode of the thin-film transistor.

A fifth aspect of the present disclosure provides a display device comprising: a substrate including a first area 1A and a second area 2A; at least one light-emitting element PX1 to PX3 disposed in the first area 1A; and at least one light-sensing element PD disposed in the second area 2A, wherein a first insulating layer is disposed on the substrate, wherein the light-emitting element is disposed on the first insulating layer, wherein a second insulating layer is disposed on the light-emitting element, wherein a buffer layer is disposed on the second insulating layer, wherein the light-sensing element is disposed on the buffer layer, wherein a passivation layer is disposed on the light-sensing element.

In some implementations of the fifth aspect, a thin-film transistor is disposed on the substrate and in the first area 1A, wherein one side electrode of the light-emitting element extends through hole of the first insulating layer so as to be connected to one electrode of the thin-film transistor.

Although the embodiments of the present disclosure have been described in more detail with reference to the accompanying drawings, the present disclosure is not necessarily limited to these embodiments, and can be modified in a various manner within the scope of the technical spirit of the present disclosure. Accordingly, the embodiments as disclosed in the present disclosure are intended to describe rather than limit the technical idea of the present disclosure, and the scope of the technical idea of the present disclosure is not limited by these embodiments. Therefore, it should be understood that the embodiments described above are not restrictive but illustrative in all respects. The scope of protection of the present disclosure should be interpreted according to the scope of claims, and all technical ideas within an equivalent scope thereto should be interpreted as being included in the scope of rights of the present disclosure.

What is claimed is:

1. A display panel, comprising:
a substrate including a first area and a second area;
at least one light-emitting element disposed in the first area and configured to emitting light; and
at least one light-sensing element disposed in the second area and configured to sense an infrared signal,
wherein the at least one light-sensing element comprises:
a first pattern including a strain inducing material patterned into a non-flat shape on the substrate; and
a thin-film semiconductor disposed on the first pattern.

2. The display panel of claim 1, wherein the second area is a non-light emitting area.

3. The display panel of claim 1, further comprising:
at least one redundant light-emitting element disposed in a corresponding manner to the at least one light-emitting element.

4. The display panel of claim 1, wherein the first pattern includes an inorganic film or an organic film.

5. The display panel of claim 1, wherein the first pattern has a convex shape or a concave shape.

6. The display panel of claim 1, wherein the first pattern is one of a hemisphere shape, a cone shape, and a pyramid shape.

7. The display panel of claim 1, wherein the non-flat shape of the first pattern has a ratio of a height and a width in a range of 0.3 to 1 or 1 to 3.

8. The display panel of claim 1, wherein the strain inducing material of the first pattern induces a stress of 1% to 3%.

9. The display panel of claim 1, wherein the strain inducing material of the first pattern induces a stress in in a uniaxial or biaxial manner.

10. The display panel of claim 1, further comprising:
an infrared ray emitter emitting an infrared signal,
wherein the at least one light-sensing element senses the emitted infrared signal reflected from an object.

11. The display panel of claim 10, wherein the infrared signal has a wavelength of 1,100 nanometers or greater.

12. The display panel of claim 1, wherein the thin-film semiconductor has a thickness of 1 to 50 nanometers.

13. The display panel of claim 1, wherein the thin-film semiconductor includes silicon.

14. The display panel of claim 1, wherein each of the at least one light-emitting element includes a micro light-emitting diode chip.

15. The display panel of claim 1, wherein each of the at least one light-emitting element includes an organic light-emitting diode.

16. The display panel of claim 1, further comprising:
a transistor formed on the substrate and configured to control an emission of the at least one light emitting element;
a first insulation layer formed on the substrate and covering the transistor; and
a second insulation layer formed on the first insulation layer,
wherein the at least one light-emitting element comprises:
a light-emitting pixel formed on the first insulation layer; and
an electrode connecting the light-emitting pixel to the transistor.

17. The display panel of claim 16, wherein the at least one light-sensing element is formed on the substrate and the first insulation layer covers the at least one light-sensing element, and
wherein the at least one light-sensing element further comprises:
a first connection electrode passing through the first and second insulation layers and connecting to a first side of the thin-film semiconductor disposed on the first pattern; and
a second connection electrode passing through the first and second insulation layers and connecting to a second side of the thin-film semiconductor disposed on the first pattern.

18. The display panel of claim 16, wherein the at least one light-sensing element is formed on the first insulation layer, and the second insulation layer covers the at least one light-sensing element, and
wherein the at least one light-sensing element further comprises:
a first connection electrode passing through the second insulation layer and connecting to a first side of the thin-film semiconductor disposed on the first pattern; and
a second connection electrode passing through the second insulation layer and connecting to a second side of the thin-film semiconductor disposed on the first pattern.

19. The display panel of claim 1, wherein the at least one light-emitting element comprises first and second light-emitting elements arranged on the substrate with one light-sensing element arranged between the first and second light-emitting elements.

20. The display panel of claim 19, wherein at least one redundant light-emitting element is further disposed between the first and second light-emitting elements.
